(19) United States
(12) Patent Application Publication
(10) Pub. No.: US 2006/0000071 A1
(43) Pub. Date: Jan. 5, 2006

(54) Process for fabrication of ultracapacitor electrodes using activated lamp black carbon

(75) Inventors: Mukta Shripad Dandekar, Maharashtra (IN); Girish Vilas Arabale, Maharashtra (IN); Vijayamohanan Kunjukrishna Pillai, Maharashtra (IN); Subhash Pundalik Vernekar, Maharashtra (IN)

Correspondence Address: NIXON & VANDERHYE, PC, 901 NORTH GLEBE ROAD, 11TH FLOOR, ARLINGTON, VA, 22203, US

(73) Assignee: Council of Scientific and Industrial Research, New Delhi (IN)

(21) Appl. No.: 10/879,509

(22) Filed: Jun. 30, 2004

(51) Int. Cl. H01L 21/00

(52) U.S. Cl. 29/25.03; 29/25.01

(57) ABSTRACT

Activated carbon obtained from lamp black has a potential application as an electrode material for ultracapacitor. The process involves activation of the lamp black carbon in the temperature range of 600-900° C. for 5-9 hours in an inert atmosphere of nitrogen and argon followed by cooling to room temperature. Cyclic voltammetric studies reveal that the obtained activated carbon has a specific capacitance values in the range 50-82 F/g in 1M H₂SO₄, and 10-25 F/g in 1M KOH. The activated carbon has a highly porous nature as realized from scanning electron microscopy and has specific (BET) surface area in the range of 300-400 m²/g.

### FIELD OF THE INVENTION

The present invention relates to an improved process for the fabrication of ultracapacitor electrodes using activated lamp black carbon. The electrodes fabricated by the process of present invention could be used in electrochemical double layer capacitors to obtain specific capacitance values in the range of 50-82 F/g. More particularly, the invention describes a method to obtain lamp black carbon from various sources followed by its activation to get enhanced charge storage ability for the fabrication of supercapacitor electrodes using acidic or alkaline electrolytes.

### BACKGROUND O THE INVENTION

Ultracapacitors, sometimes also known as double layer capacitors or supercapacitors are electrochemical devices for storing and releasing energy at a flexible rate. For example, these devices can be charged and discharged at fast (less than few seconds) or slow (few days) rates without having any adverse effects on the efficiency. Batteries, fuel cells, and supercapacitors are the three main electrochemical energy storage devices, where the selection of the electrode and electrolyte materials controls the utility of energy storage. Ultracapacitors are distinctly different from batteries and fuel cells since they can be charged and discharged at much faster rates and consequently their power density is about 200 times more. Nevertheless many electrode fabrication and engineering aspects are similar to those of battery and fuel cell electrode production including electrode sealing, electrolyte usage, and packaging. These devices are especially useful for several applications like hybrid power systems, electric vehicles, military and medical applications, actuators and motor drive where high rate and short pulse delivery of charges are important.

Different types of electrode materials are used for the fabrication of ultracapacitors. Carbon is one such commonly used material for the fabrication of ultracapacitor electrodes due to its unique advantages such as electrochemical inertness within a wide potential window (up to 1 V in aqueous and up to 3.5 V in non-aqueous media), simple preparation methods from inexpensive raw materials such as coconut shell, wood, cellulose, peat, bone, coal tar, resin and resorcinol-formaldehyde and related polymers through gas phase (steam, nitrogen, argon etc.) activation at higher temperatures, possibility to tune porosity and surface area by activation, ease of surface manipulation by chemical modification, good conductivity, oxidation stability and mechanical strength to form electrodes on a variety of current collecting metallic materials. Consequently, carbon is used for different applications such as electrode material in fuel cells and ultracapacitors, for adsorption and removal of impurities from drinking water, for removal of harmful organic compounds from industrial waste etc. For ultracapacitor and fuel cell applications, conductivity, surface area, and porosity play a particularly significant role since the structure of the electrode-electrolyte interface controls the reactions rate. For example, different forms of carbon such as activated carbon, mesoporous aerogels, and carbon nanotubes show different charge storage ability. Among different carbon materials activated carbon is especially attractive for fabricating ultracapacitor electrodes since its porosity, surface area and conductivity can be tuned using appropriate activation procedure. However, this amount of charge storage is not sufficient for several practical applications of ultracapacitors, and hence several attempts are being made worldwide to enhance the specific capacitance of carbon electrodes. One way to improve the capacitance is by using carbon-metal oxide composites such as RuO₂, IrO₂, and NiOₓ, which are known to give large capacitance values owing to their pseudocapacitive behavior. Nevertheless, their commercial applications are limited because of the high cost of Ru and Ir compounds.

Reference may be made to U.S. Pat. No. (6,544,648) dated 8^{th} Apr. 2003, wherein carbon material having specific area of 1400 m²/g, produced at elevated temperature and pressure shows a specific capacitance of 54 F/g. The main limitation of the process is that the electrode material though having high surface area do not show high specific capacitance value. Reference may also be made to Journal of Physics and Chemistry of Solids 65 (2004) 275-280, wherein carbon fabrics from viscous fibers activated with KOH have been investigated as possible materials for electrochemical capacitors. In this process the fibers were first pyrolysed at 400 or 600° C. followed by immersion in KOH solutions with various carbon to KOH ratios before activation in argon atmosphere in the temperature range of 700-800° C. The main drawback here is that the process of producing KOH treated carbon fabrics is time consuming and further involves corrosive alkali treatment. Reference may also be made to Chinese Pat.25 (2), 247-251(1997), wherein a carbonized resorcinol-formaldehyde aerogel was prepared from resorcinol and formaldehyde by sol-gel method using supercritical drying followed by carbonization at ≦1000° C. The double layer capacitance was found to be 30 F/g. The main drawback of this work is the use of supercritical method, which is hazardous and expensive for practical applications. Another limitation is that high-pressure experimental set-up is cumbersome both to maintain and to use. Reference may be made to U.S. Pat. No. (6,383,363) dated 7^{th} May 2002 wherein, ruthenium oxide is used as electrode material giving high specific capacitance value although ruthenium oxide is quite expensive to be used for commercial applications. Reference may be made to Carbon 42 (2004) 451-453, wherein composite materials like RuO₂.xH₂O/Carbon nanotubes has been used for fabricating electrode to get a specific capacitance values of 295 F/g. However, when very expensive RuO₂ is not used, carbon nanotubes alone gives very poor capacitance (27 F/g) and hence this material may not be useful for fabricating ultracapacitor device. The above-mentioned patents describe many of the considerations involved in producing useful ultracapacitor electrodes; one common limitation is that their specific capacitance values are comparatively less, if expensive metal oxides like RuO₂ and IrO₂ are not used. More significantly the resistance of the carbon is large causing large RC time constant, resulting in poor response time. Thus there exists a need to obtain better, less expensive electrode materials, with enhanced specific capacitance values for several thousands cycles of operation considering their potential utility in industrial applications.

### OBJECT OF THE INVENTION

The main object of the present invention is to provide an improved process for the fabrication of ultracapacitor electrodes using activated lamp black carbon, which obviates the drawbacks as detailed above.

Another object of the present invention is to obtain activated carbon from lamp black by a very simple activation process in an inert atmosphere of nitrogen; argon in the range 600-900° C. for a period in the range 5-9 hours.

Still another object of the present invention is to provide a simple method to fabricate electrode for electrochemical charge storage measurements.

Yet another object of the present invention is to provide activated carbon from lamp black giving specific capacitance ranging from 50-82 F/g in 1M H₂SO₄ and 10-25 F/g in 1M KOH, depending on the conditions such as temperature, flow rate of the gas and heating rate maintained during activation and the electrolytes used for the electrochemical measurements.

### BRIEF DESCRIPTION OF THE ACCOMPANYING DRAWINGS

FIG. 1 is a cyclic voltammogram of the activated lamp black carbon at a scan rate of 1 mV/s in 1M H₂SO₄.

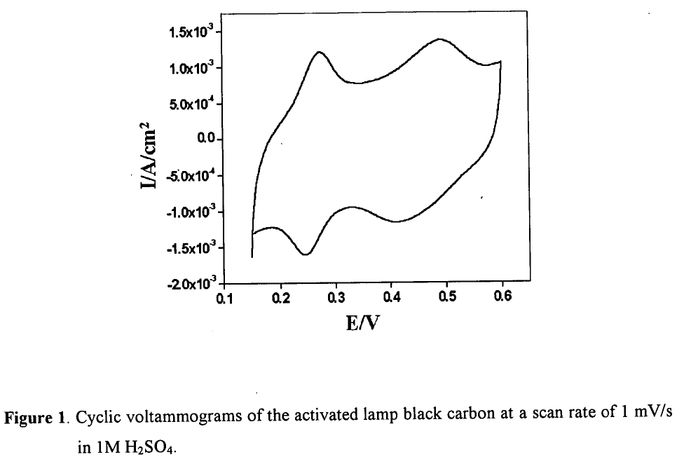

FIG. 2 is a cyclic voltammogram of an activated lamp black carbon at a scan rate of 1 mV/s in 1M KOH.

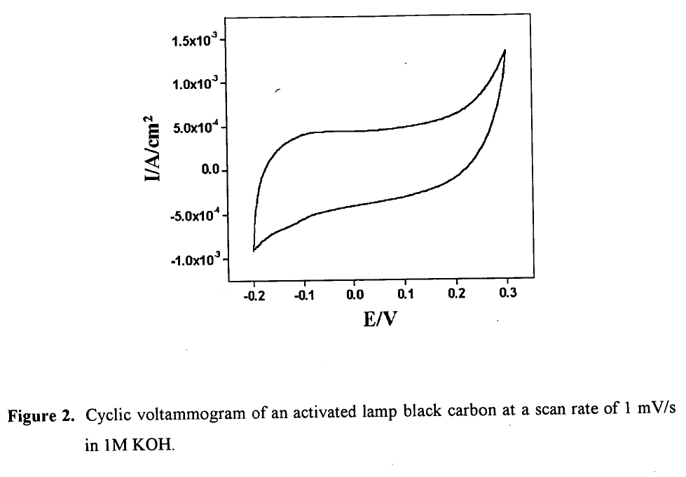

Table 1 below gives the specific capacitance (F/g) values obtained by cyclic voltammetry.

TABLE 1
Specific capacitance (F/g) values obtained by cyclic voltammetry

| | Technique | | Scan rate | Specific |
|---|---|---|---|---|
| No. | used | Electrolyte | (mV/s) | capacitance (F/g) |
| | Cyclic | 1 M H₂SO₄ | 1 mV/s | 82 |
| | voltammetry | | | |
| | Cyclic | 1 M KOH | 1 mV/s | 20 |
| | voltammetry | | | |

### SUMMARY OF THE INVENTION

Accordingly, the present invention provides an improved process for the fabrication of ultracapacitor electrodes using activated lamp black carbon which comprises burning a fatty substance in a lamp using a cotton wick, collecting the soot over the flame on a metallic surface to obtain carbon deposit, grinding the carbon deposit to form a homogeneous mixture, activating the homogeneous mixture of carbon to obtain activated lamp black carbon, fabricating a working electrode by thoroughly mixing the activated lamp black carbon with graphite and binder in a solvent and pasting the mixture on a stainless steel mesh used as a current collector to carry out the electrochemical measurements in H₂SO₄ or KOH electrolyte to get a specific capacitance in the range of 50-82 F/g.

In one embodiment of the invention the fatty substance used is selected from the group consisting of butter oil and vegetable oils selected in turn from the group consisting of groundnut oil and sunflower oil.

In another embodiment of the invention, the carbon in the vapor phase is deposited on the metal substrate by condensation process.

In another embodiment of the present invention, the binder may be ethyl cellulose, polybenzimidazole, polyvinyl alcohol, polyvinyl stearate, and polytetrafluoroethylene.

In yet another embodiment, the solvent may be tetrahydrofuran, N,N-dimethylacetamide, ethyl alcohol and isopropyl alcohol.

In yet another embodiment, the ratio of activated lamp black carbon, graphite and binder, is 75:20:5, 80:10:10, 80:15:5.

In another embodiment of the invention, the homogeneous mixture of carbon is activated by heating at a temperature in the range of 600-900° C. for 5-9 hours in an inert atmosphere of nitrogen or argon.

### DETAILED DESCRIPTION OF THE INVENTION

In the present invention a method to prepare activated lamp black carbon has been disclosed. The method is found to be very economical and the material is found to be very good for fabricating ultracapacitor electrodes. The process in the preparation of activated lampblack carbon involves two major steps namely, burning of fatty substance, preferably but not necessarily, containing mainly ketones and lactones obtained from milk commonly called as butter oil, and vegetable oils from various sources such as groundnut oil, sunflower oil, etc. in a lamp with the help of a cotton wick and collecting lamp black by contact of the flame to the metal surface, where elemental carbon in vapor phase is deposited on the metal substrate by condensation method followed by activation of lamp black in the temperature range of 600-900° C. for 5-9 hours in an atmosphere of nitrogen or argon.

This method is economical and is not a time consuming process as compared to other activation processes such as obtaining activated carbon from sources such as coconut shell, wood, bone, cellulose and various other carbonaceous materials.

The process of the present invention is described herein below with reference to examples, which are illustrative only and should not be construed to limit the scope of the present invention, in any manner.

### EXAMPLE 1

In this example fatty substances specifically butter oil was burnt with the help of a cotton wick in a lamp. The lamp black carbon was collected by contact of the flame to a metallic surface where carbon in the vapor phase was deposited on the metal substrate by condensation process. The obtained lamp black carbon was mechanically ground to obtain uniform particle size. The homogenized lamp black carbon was then activated in a tubular furnace at higher temperature of 900° C. for 9 hours maintaining the heating rate of 5° C./min in an inert atmosphere of nitrogen with a flow rate of 20 ml/min. Specific capacitance of the activated lamp black carbon was measured by cyclic voltammetry wherein the working electrode was fabricated by mechanically grinding a mixture containing 75% activated lamp black carbon, 20% graphite and 5% ethyl cellulose binder to produce homogenized mixture which was then pasted on to a stainless steel mesh using tetrahydrofuran as a solvent. The electrode was then pressed at room temperature and then at 155° C. for two minutes at a pressure of 200 psi. Platinum foil was used as the counter electrode and Hg/Hg₂SO₄ as a reference electrode. The specific capacitance was measured to be 82 F/g in 1M H₂SO₄. The specific surface area was measured by BET method and was calculated to be 370 m²/g.

### EXAMPLE 2

Lamp black carbon was obtained as given in example 1. The homogenized lamp black carbon was then activated in a tubular furnace at a higher temperature of 800° C. for 7 hours maintaining the heating rate of 10° C./min in an inert atmosphere of nitrogen with a flow rate of 25 ml/min. Specific capacitance of the activated lamp black carbon was measured by cyclic voltammetry where the working electrode was fabricated by mechanically grinding a mixture containing 75% activated lamp black carbon, 20% graphite and 5% ethyl cellulose binder to produce homogenized mixture which was then pasted on to a stainless steel mesh using tetrahydrofuran as a solvent. The electrode was then pressed at room temperature and then at 160° C. for two minutes at a pressure of 200 psi. Platinum foil was used as a counter electrode and Hg/HgO as a reference electrode. The specific capacitance was measured to be 20 F/g in 1M KOH. Specific surface area was measured to be 350 m²/g by BET method.

### EXAMPLE 3

In this example vegetable oil obtained from groundnut was burnt with the help of a cotton wick in a lamp. The lamp black carbon was collected by contact of the flame to a metallic surface where carbon in vapor phase was deposited on the metal substrate by condensation process. The homogenized lamp black carbon was then activated in a tubular furnace at higher temperature of 600° C. for 8 hours maintaining the heating rate of 5° C./min in an inert atmosphere of argon with a flow rate of 20 ml/min. Specific capacitance of the activated lamp black carbon was measured by cyclic voltammetry wherein the working electrode was fabricated by mechanically grinding a mixture containing 75% activated lamp black carbon, 20% graphite and 5% ethyl cellulose binder to produce homogenized mixture which was then pasted on a stainless steel mesh with the help of tetrahydrofuran as a solvent. The electrode was then pressed at room temperature and then at 160° C. for two minutes at a pressure of 200 psi. Platinum foil was used as a counter electrode and Hg/Hg₂SO₄ as a reference electrode. The specific capacitance was measured to be 1 F/g in 1M H₂SO₄.

### EXAMPLE 4

Lamp black carbon was obtained as described in example 1. The homogenized lamp black carbon was then activated in a tubular furnace at higher temperature of 900° C. for 9 hours maintaining the heating rate of 5° C./min in an inert atmosphere of nitrogen with a flow rate of 20 ml/min. Specific capacitance of the activated lamp black carbon was measured by cyclic voltammetry wherein the working electrode was fabricated by mechanically grinding a mixture containing 75% activated lamp black carbon, 20% graphite and 5% polybenzimidazole binder to produce homogenized mixture which was then pasted on a stainless steel mesh with the help of N,N-dimethylacetamide as a solvent. The electrode was then pressed at room temperature and then at 200° C. for two minutes at a pressure of 200 psi. Platinum foil was used as a counter electrode and Hg/Hg₂SO₄ as a reference electrode. The specific capacitance was measured to be 56 F/g in 1M H₂SO₄. Specific surface area was measured to be 370 m²/g by BET method.

### EXAMPLE 5

Lamp black carbon was obtained as described in example 1. The homogenized lamp black was then activated in a tubular furnace at higher temperature of 800° C. for 7 hours maintaining the heating rate of 10° C./min in an inert atmosphere of nitrogen with a flow rate of 25 ml/min. Specific capacitance of the activated lamp black carbon was measured by cyclic voltammetry wherein the working electrode was fabricated by mechanically grinding a mixture containing 75% activated lamp black carbon, 20% graphite and 5% polybenzimidazole binder to produce homogenized mixture which was then pasted on a stainless steel mesh with the help of N,N-dimethylacetamide as a solvent. The electrode was then pressed at room temperature and then at 200° C. for two minutes at a pressure of 200 psi. Platinum foil was used as a counter electrode and Hg/HgO as a reference electrode. The specific capacitance was measured to be 16 F/g in 1M KOH. Specific surface area was measured to be 350 m²/g by BET method.

### THE MAIN ADVANTAGES OF THE PRESENT INVENTION ARE

1. an easy and economical procedure for obtaining activated carbon from lamp black, especially suitable for fabricating ultracapacitor electrode;

2. the use of activated carbon from lamp black as an ultracapacitor electrode material for according to present invention with a specific capacitance value of 82 F/g in 1M H₂SO₄ at a scan rate of 1 mV/s;

3. the preparation of lamp black carbon as an electrode material for ultracapacitor is simple without the need for any high temperature activation, 4. the invention has performance characteristics like time response far exceeding the existing carbon based ultracapacitor;

5. certain difficulties due to high resistance of the activated carbon are generally avoided by mixing a large amount of graphite, which is not essential as per the present invention since the carbon itself has high conductivity.

We claim:

1. A process for the fabrication of ultracapacitor electrodes using activated lamp black carbon which comprises burning a fatty substance in a lamp using a cotton wick, collecting the soot over the flame on a metallic surface to obtain carbon deposit, grinding the carbon deposit to form a homogeneous mixture, activating the homogeneous mixture of carbon to obtain activated lamp black carbon, fabricating a working electrode by thoroughly mixing the activated lamp black carbon with graphite and binder in a solvent and pasting the mixture on a stainless steel mesh used as a current collector to carry out the electrochemical measurements in H₂SO₄ or KOH electrolyte to get a specific capacitance in the range of 50-82 F/g.

2. A process as claimed in claim 1 wherein the fatty substance used is selected from the group consisting of butter oil and vegetable oils selected in turn from the group consisting of groundnut oil and sunflower oil.

3. A process as claimed in claim 1 wherein the carbon in the vapor phase is deposited on the metal substrate by condensation process.

4. A process as claimed in claim 1 wherein the binder is selected from the group consisting of ethyl cellulose, polybenzimidazole, polyvinyl alcohol, polyvinyl stearate, and polytetrafluoroethylene.

5. A process as claimed in claim 1 wherein the solvent is selected from the group consisting of tetrahydrofuran, N,N-dimethylacetamide, ethyl alcohol and isopropyl alcohol.

6. A process as claimed in claim 1 wherein the ratio of activated lamp black carbon, graphite and binder is 75:20:5, 80:10:10 or 80:15:5.

7. A process as claimed in claim 1 wherein the homogeneous mixture of carbon is activated by heating at a temperature in the range of 600-900° C. for 5-9 hours in an inert atmosphere of nitrogen or argon.
